(19) United States
(12) Patent Application Publication
(10) Pub. No.: US 2007/0024322 A1
(43) Pub. Date: Feb. 1, 2007

(54) Leakage current reduction scheme for domino circuits

(76) Inventors: Yibin Ye, Portland, OR (US); Siva G. Narendra, Portland, OR (US); Vivek K. De, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/194,946

(22) Filed: Aug. 1, 2005

(51) Int. Cl. H03K 19/096

(52) U.S. Cl. 326/98

(57) ABSTRACT

A method and system for leakage current reduction in domino circuits is described. The system includes a domino circuit with a dynamic gate, a static gate, and a standby signal to set the domino circuit to an evaluate phase during an inactive mode. The inputs to the static gate are set to low and the inputs to the dynamic gate are set to high during the inactive mode. The standby signal may be an input to a device in the dynamic gate or an input to a latch coupled to the dynamic gate.

### TECHNICAL FIELD

Embodiments of the invention relate to circuits, and more specifically to a leakage current reduction scheme for domino circuits.

### BACKGROUND

Digital circuits typically use domino logic. As shown in FIG. 1, a typical domino path 100 includes alternating cascaded dynamic gates, such as 104, 108, and 112, and static gates, such as 106, 110, and 114. There may be multiple stages of these gates between the input latch or flip flop, such as 102, and the output latch or flip flop, such as 116. Domino logic has two phases: precharge and evaluate. FIG. 1 shows the outputs of each gate in the precharge phase.

When domino circuits in a functional unit are not active, the circuits are usually in the precharge stage. The leakage paths during precharge are through NMOS (Negative-channel Metal Oxide Semiconductor) devices in the dynamic stage and through PMOS (Positive-channel Metal Oxide Semiconductor) devices in the static stage. NMOS paths in a dynamic stage are usually the evaluate paths which determine gate performance. Therefore, NMOS devices in a dynamic stage tend to be large in size and may use lower Vt devices. As a result, leakage through NMOS devices in a dynamic stage are often large. In a static stage, PMOS devices are often large and may use lower Vt devices. As a result, leakage through PMOS devices in a static stage are often large. Therefore, when the domino circuits are not active, there is significant leakage through the MOS devices.

### BRIEF DESCRIPTION OF THE DRAWINGS

The invention is illustrated by way of example, and not by way of limitation, in the figures of the accompanying drawings in which like reference numerals refer to similar elements.

FIG. 1 is a block diagram illustrating a typical domino path.

FIG. 2a is a circuit diagram illustrating a typical domino circuit in precharge phase.

FIG. 2b is a circuit diagram illustrating a typical domino circuit in evaluate phase.

FIG. 3 is a block diagram illustrating a domino path according to one embodiment of the invention.

FIG. 4 is a block diagram illustrating a domino path according to one embodiment of the invention.

FIG. 5 is a circuit diagram illustrating a domino circuit according to one embodiment of the invention.

FIG. 6 is a flow diagram illustrating a method according to an embodiment of the invention.

FIG. 7 is a block diagram illustrating a suitable computing environment in which certain aspects of the illustrated invention may be practiced.

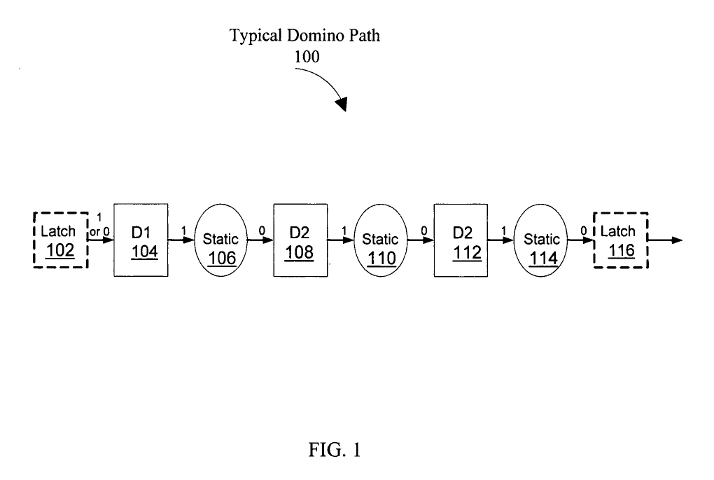

### DETAILED DESCRIPTION

Embodiments of a system and method for leakage current reduction in domino circuits are described. In the following description, numerous specific details are set forth. However, it is understood that embodiments of the invention may be practiced without these specific details. In other instances, well-known circuits, structures and techniques have not been shown in detail in order not to obscure the understanding of this description.

Reference throughout this specification to “one embodiment” or “an embodiment” means that a particular feature, structure, or characteristic described in connection with the embodiment is included in at least one embodiment of the invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

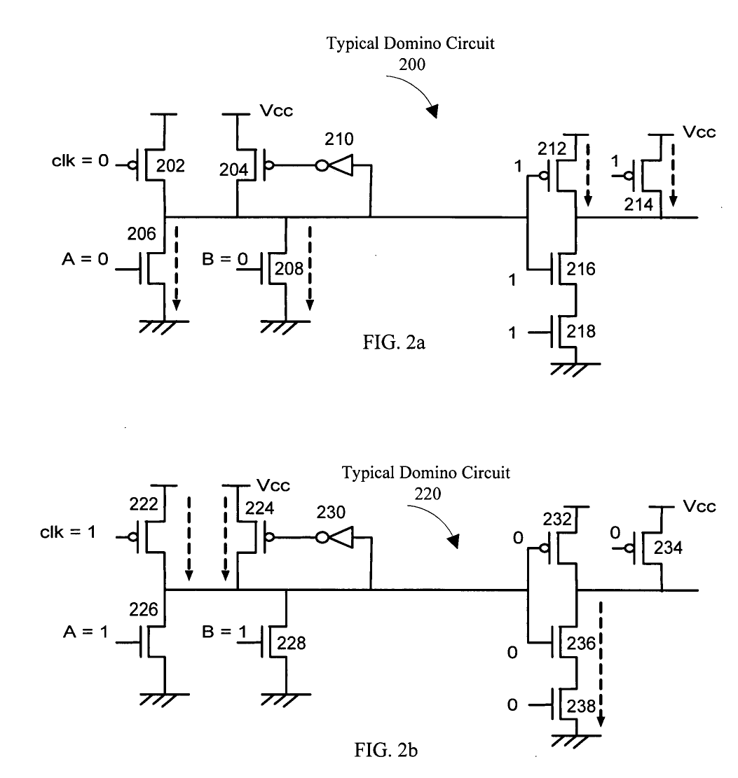

FIGS. 2a-2b are circuit diagrams illustrating typical domino circuits. FIG. 2a shows a typical domino circuit in precharge phase, while FIG. 2b shows a typical domino circuit in evaluate phase. As shown, a domino circuit typically includes a dynamic gate and a static gate. In circuit 200, the dynamic gate is formed by circuit elements 202-210 and the static gate is formed by circuit elements 212-218. In circuit 220, the dynamic gate is formed by circuit elements 222-230 and the static gate is formed by circuit elements 232-238.

In the precharge phase, as shown in FIG. 2a, the clock (clk) is low and other inputs to the dynamic stage are also low. Since the inputs to the NMOS devices 206 and 208 are low, the NMOS devices are off. The output of the dynamic stage is precharged to high. The inputs to the static stage are high, so the output of the static stage is low. The leakage paths in the precharge stage, shown by the dotted arrows, are through the NMOS devices in the dynamic gate and through the PMOS devices in the static gate.

In the evaluate stage, as shown in FIG. 2b, the clock is high and other inputs to the dynamic stage are also high. The output of the dynamic stage is low. The inputs to the static stage are low, so the output of the static stage is high. The leakage paths in the evaluate stage, shown by the dotted arrows, are through the PMOS devices in the dynamic gate and through the NMOS devices in the static gate.

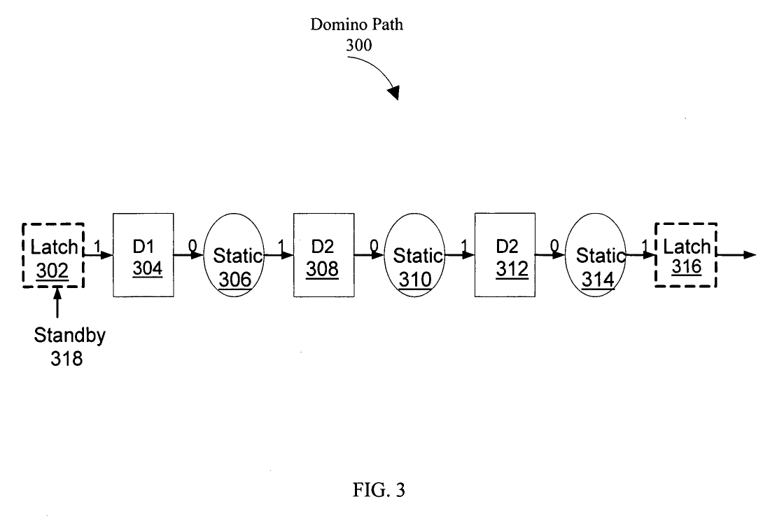

FIG. 3 illustrates a domino path 300 according to one embodiment of the invention. The domino path 300 includes alternating cascaded dynamic gates, such as 304, 308, or 312, and static gates, such as 306, 310, or 314. There may be multiple stages of these gates between input latch or flip flop 302 and output latch or flip flop, 316. A standby signal 318 sets the output of latch or flip flop 302 to high. This causes the inputs to the first domino stage 304 to be high. Therefore, the output of the domino stage 304 is low. Since the inputs to the first static stage 306 is low, the output of the static stage 306 is high. The inputs to the second domino stage 308 are high, so the output of the domino stage 308 is low. This causes the output of the second static stage 310 to be high. Therefore, the output of the third domino stage 312 to be low and the output of the third static stage 314 is high. Further alternating cascaded dynamic and static stages may follow with similar alternating low and high outputs.

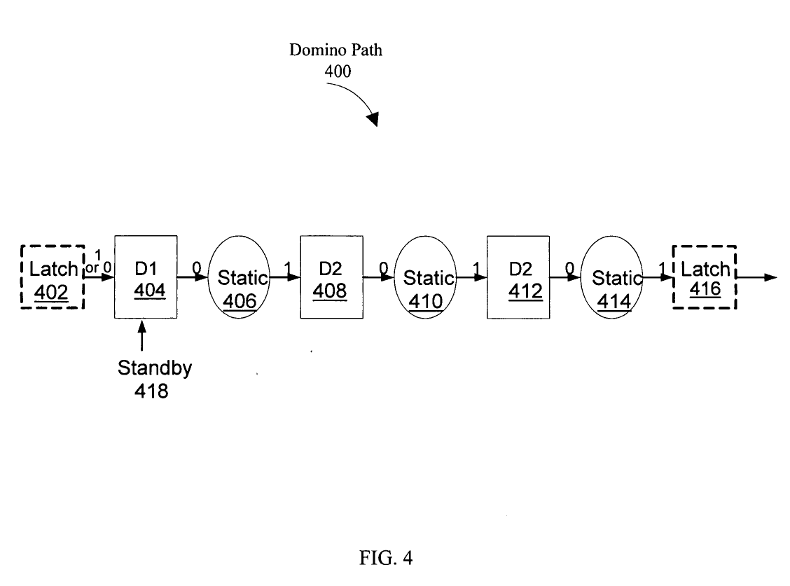

FIG. 4 illustrates a domino path 400 according to one embodiment of the invention. The domino path 400 includes an input latch or flip flop 402, an output latch or flip flop 416 and alternating cascaded dynamic gates, such as 404, 408, or 412, and static gates, such as 406, 410, or 414. In this embodiment, the output of latch 400 may be high or low. A standby signal 418 sets the output of the first domino stage 404 to low. Since the inputs to the first static stage 406 are low, the output of static stage 406 is high. The inputs to the second domino stage 408 are high, so the output of the domino stage 408 is low. This causes the output of the second static stage 410 to be high. Therefore, the output of the third domino stage 412 is low and the output of the third static stage 414 is high. Further alternating cascaded dynamic and static stages may follow with similar alternating low and high outputs.

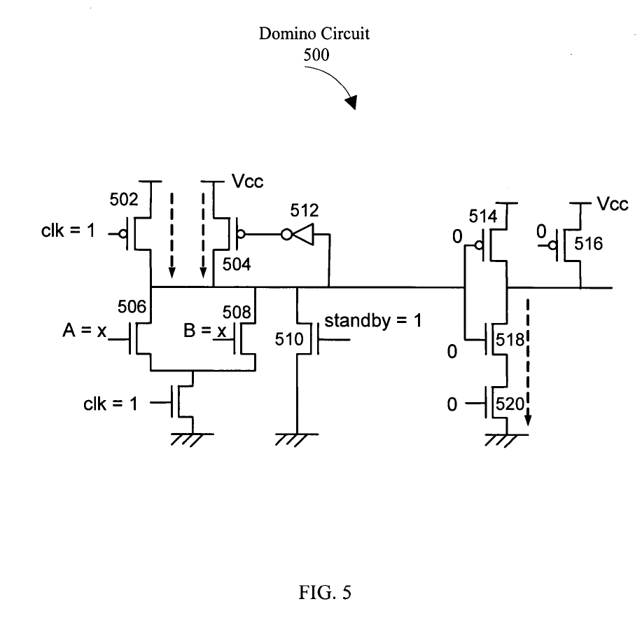

FIG. 5 is a circuit diagram illustrating a domino circuit 500 according to an embodiment of the invention. The domino circuit 500 includes a dynamic gate formed by circuit elements 502-512 and a static gate formed by circuit elements 514-520. In one embodiment, as shown, circuit elements 502, 504, 514, and 516 are PMOS devices and circuit elements 506, 508, 510, 518, and 520 are NMOS devices. In one embodiment, a standby signal is the input to NMOS device 510. The standby signal 510 is set to high when the domino circuit is in an inactive mode. The clock signal, clk, is also set to high. This causes domino circuit 500 to be in evaluate phase during the inactive mode. Other inputs to the dynamic stage may be high or low. For example, inputs A and B are from regular latches or flip-flops and may be high or low. The output of the dynamic stage will be low. The inputs to the static stage will be low and the output of the static stage will be high.

The leakage paths, as shown by the dotted arrows, will be through the PMOS devices in the dynamic stage and through the NMOS devices in the static stage. Since PMOS devices tend to be smaller in size than NMOS devices in the dynamic stage and NMOS devices tend to be smaller in size than PMOS devices in the static stage, setting the domino circuit to evaluate during the inactive mode reduces the leakage of the MOS devices. In one embodiment, dual-Vt is used for further reduction in leakage by using high-Vt devices for precharge devices and using low-Vt devices for evaluate devices.

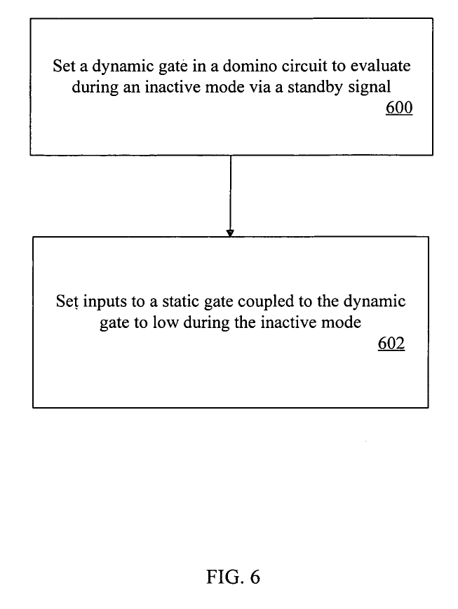

FIG. 6 illustrates a method according to one embodiment of the invention. At 600, a dynamic gate in a domino circuit is set to evaluate during an inactive mode via a standby signal. In one embodiment, the dynamic gate includes one or more PMOS devices and one or more NMOS devices. In one embodiment, the standby signal is an input to one of the NMOS devices. In one embodiment, the standby signal is set to high during the inactive mode. In one embodiment, the domino circuit includes a latch coupled to the dynamic gate. In one embodiment, the standby signal is used to set the output of the latch to high during the inactive mode. The inputs to the dynamic gate are then set to high and the output of the dynamic gate set to low during the inactive mode.

At 602, inputs to a static gate coupled to the dynamic gate are set to low during the inactive mode. In one embodiment, the static gate includes one or more PMOS devices and one or more NMOS devices. In one embodiment, the domino circuit may include other dynamic gates and static gates. The inputs to the other dynamic gates may be set to high, which causes the outputs of the dynamic gates to be low. The inputs to the other static gates may be set to low, which causes the outputs of the static gates to be high.

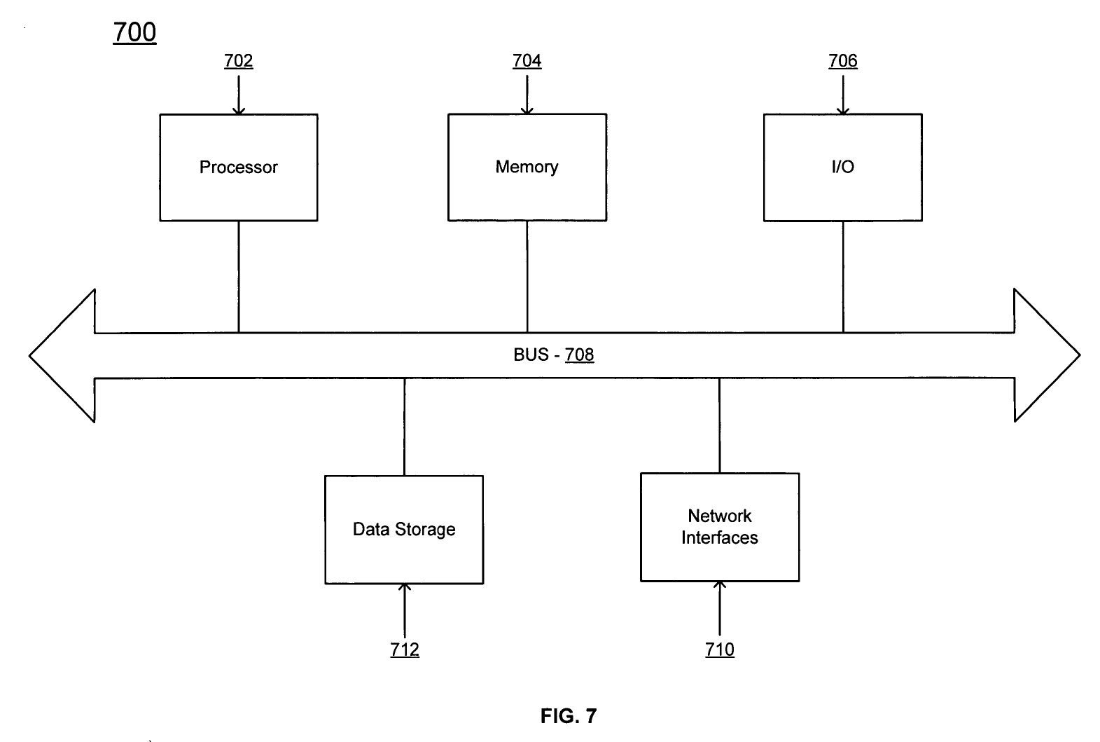

FIG. 7 is a block diagram illustrating a suitable computing environment in which certain aspects of the illustrated invention may be practiced. In one embodiment, the method described above may be implemented on a computer system 700 having components that include a processor 702, a memory 704, an Input/Output (I/O) device 706, a data storage device 712, and a network interface 710, coupled to each other via a bus 708. The components perform their conventional functions known in the art and provide the means for implementing the system of the invention. Collectively, these components represent a broad category of hardware systems, including but not limited to general purpose computer systems, mobile or wireless computing systems, and specialized packet forwarding devices. It is to be appreciated that various components of computer system 700 may be rearranged, and that certain implementations of the present invention may not require nor include all of the above components. Furthermore, additional components may be included in system 700, such as additional processors (e.g., a digital signal processor), storage devices, memories (e.g. RAM, ROM, or flash memory), and network or communication interfaces.

While the invention has been described in terms of several embodiments, those of ordinary skill in the art will recognize that the invention is not limited to the embodiments described, but can be practiced with modification and alteration within the spirit and scope of the appended claims. The description is thus to be regarded as illustrative instead of limiting.

What is claimed is:

1. A domino circuit comprising:
a dynamic gate responsive to a standby signal to set the dynamic gate into an evaluate phase when in an inactive mode; and
a static gate, coupled to the dynamic gate, with inputs to the static gate set to low during the inactive mode in response to the standby signal.

2. The circuit of claim 1, wherein the dynamic gate comprises one or more PMOS devices.

3. The circuit of claim 1, wherein the dynamic gate comprises one or more NMOS devices.

4. The circuit of claim 3, wherein an input to at least one of the NMOS devices is the standby signal.

5. The circuit of claim 4, wherein the standby signal is set to high during the inactive mode.

6. The circuit of claim 1, wherein the static gate comprises one or more PMOS devices.

7. The circuit of claim 1, wherein the static gate comprises one or more NMOS devices.

8. The circuit of claim 1, further comprising a latch coupled to the dynamic gate.

9. The circuit of claim 1, further comprising an additional dynamic gate coupled to the static gate, wherein inputs to the additional dynamic gate are set to high during the inactive mode.

10. The circuit of claim 9, further comprising an additional static gate coupled to the additional dynamic gate, wherein inputs to the additional static gate are set to low during the inactive mode.

11. A method comprising:
setting a dynamic gate in a domino circuit to evaluate during an inactive mode via a standby signal; and
setting inputs to a static gate coupled to the dynamic gate to low during the inactive mode.

12. The method of claim 11, wherein setting the dynamic gate in the domino circuit to evaluate during the inactive mode via the standby signal comprises including the standby signal as an input to the dynamic gate.

13. The method of claim 12, wherein including the standby signal as an input to the dynamic gate comprises including the standby signal as an input to a NMOS device of the dynamic gate.

14. The method of claim 11, further comprising setting the standby signal to high during the inactive mode.

15. The method of claim 11, wherein setting the dynamic gate in the domino circuit to evaluate during the inactive mode via the standby signal comprises setting inputs to the dynamic gate to be high during the inactive mode.

16. The method of claim 15, wherein setting inputs to the dynamic gate to be high during the inactive mode comprises including the standby signal as an input to a latch coupled to the dynamic gate and setting the output of the latch to high during the inactive mode via the standby signal.

17. A system comprising:
a network interface; and
a processor coupled to the network interface, the processor including a domino circuit, the domino circuit including:
a dynamic gate responsive to a standby signal to set the dynamic gate into an evaluate phase when in an inactive mode; and
a static gate, coupled to the dynamic gate, with inputs to the static gate set to low during the inactive mode in response to the standby signal.

18. The system of claim 17, wherein the dynamic gate comprises one or more PMOS devices.

19. The system of claim 18, wherein the dynamic gate comprises one or more NMOS devices.

20. The system of claim 19, wherein at least one of the NMOS devices has the standby signal as an input.
